(19) United States
(12) Patent Application Publication
(10) Pub. No.: US 2026/0045283 A1
(43) Pub. Date: Feb. 12, 2026

(54) MEMORY SYSTEM

(71) Applicant: SK hynix Inc., Gyeonggi-do (KR)

(72) Inventor: Jung Taek YOU, Gyeonggi-do (KR)

(21) Appl. No.: 18/976,363

(22) Filed: Dec. 11, 2024

(30) Foreign Application Priority Data
Aug. 8, 2024 (KR) 10-2024-0106107

(51) Int. Cl. G11C 7/10

(52) U.S. Cl. CPC G11C 7/1066; G11C 7/1045; G11C 7/1063; G11C 2207/2254

(57) ABSTRACT

A memory system may include a first memory configured to receive a first signal in synchronization with a clock, and a second memory configured to receive a second signal in synchronization with the clock. The first memory may transmit the received first signal to the second memory and the second memory may transmit the received second signal to the first memory.

### CROSS-REFERENCE TO RELATED APPLICATION

This application claims priority under 35 U.S.C. § 119(a) to Korean Patent Application No. 10-2024-0106107 filed on Aug. 8, 2024, which is incorporated herein by reference in its entirety.

### BACKGROUND

### 1. Technical Field

Embodiments of the present disclosure relate to an integrated circuit technology, and to a memory system.

### 2. Related Art

Recently, with the miniaturization, low power consumption, high performance, diversification, and the like of electronic devices, there is a demand for memories capable of storing information in various electronic apparatuses such as computers and portable communication devices.

For example, a memory system is configured to include a plurality of memories, and perform a training operation in order to control the memories at the same timing.

### SUMMARY

In an embodiment of the present disclosure, a memory system may include a first memory configured to receive a first signal in synchronization with a clock; and a second memory configured to receive a second signal in synchronization with the clock. The first memory may transmit the received first signal to the second memory and the second memory may transmit the received second signal to the first memory.

In another embodiment of the present disclosure, a memory system may include a first memory including a plurality of first connection pads configured to electrically connect with a controller and a plurality of first memory connection pads configured to electrically connect with a second memory; and the second memory including a plurality of second connection pads configured to electrically connect with the controller and a plurality of second memory connection pads configured to electrically connect with the first memory.

In further another embodiment of the present disclosure, a memory system may include a first memory configured to receive a first chip select signal in synchronization with a clock; a second memory configured to receive a second chip select signal in synchronization with the clock; and a controller configured to transmit the first chip select signal to the first memory and transmit the second chip select signal to the second memory. The first memory may transmit the received first chip select signal to the second memory as a first internal chip select signal, and the second memory may transmit the received second chip select signal to the first memory as a second internal chip select signal.

### BRIEF DESCRIPTION OF THE DRAWINGS

FIG. 1 is a diagram for describing a configuration of a memory system in accordance with an embodiment of the present disclosure.

FIG. 2 is a diagram for describing a detailed configuration of the memory system in accordance with the embodiment of the present disclosure.

FIGS. 3 and 4 are timing diagrams for describing the operation of the memory system in accordance with the embodiment of the present disclosure.

FIG. 5 is a diagram for describing a configuration of a memory system in accordance with another embodiment of the present disclosure.

FIG. 6 is a diagram for describing a configuration of a memory system in accordance with further another embodiment of the present disclosure.

### DETAILED DESCRIPTION

Various embodiments of the present disclosure are directed to providing a memory system that can control memories at the same timing through a training operation.

It is possible to effectively prevent an operation failure of a memory system including a plurality of memories.

Hereafter, embodiments in accordance with the technical spirit of the present disclosure will be described with reference to the accompanying drawings.

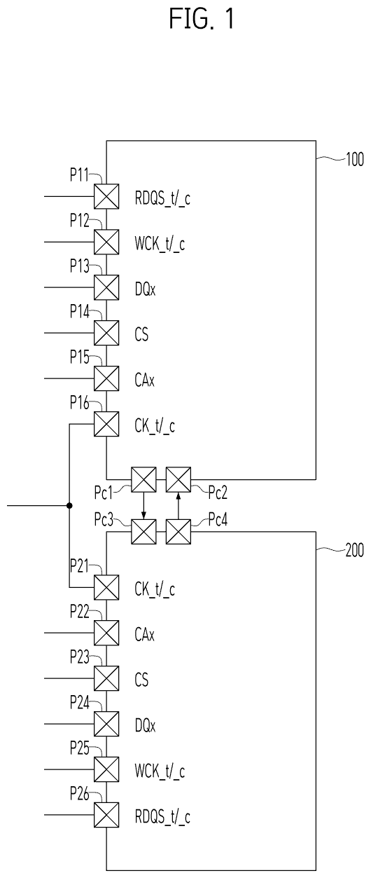

FIG. 1 is a diagram for describing a configuration of a memory system in accordance with an embodiment of the present disclosure.

Referring to FIG. 1, the memory system may include a plurality of memories. Each of the plurality of memories may include a plurality of external connection pads and a plurality of memory connection pads. The external connection pads may be pads for electrically connecting the memory with an external device. The memory connection pads may be pads for electrically connecting the memory with the memory.

In an embodiment, the memory system may include a first memory 100 and a second memory 200.

In an embodiment, the first memory 100 may include first to sixth external connection pads P11, P12, P13, P14, P15, and P16 and first and second memory connection pads Pc1 and Pc2.

In an embodiment, the first memory 100 may be electrically connected to the external device by using the first to sixth external connection pads P11, P12, P13, P14, P15, and P16.

When the external device is a controller, the first memory 100 may receive signals for being controlled by the controller and transmit signals to the controller through the first to sixth external connection pads P11, P12, P13, P14, P15, and P16. For example, the signals transmitted and received to and from the controller may include a first clock CK_t/_c, a command address signal CAx, a chip select signal CS, a data signal DQx, a second clock signal WCK_t/_c, and a data strobe signal RDQS_t/_c. In an embodiment, the first memory 100 may transmit the data strobe signal RDQS_t/_c to the controller through the first external connection pad P11. The first memory 100 may receive the second clock signal WCK_t/_c from the controller through the second external connection pad P12. The first memory 100 may transmit and receive the data signal DQx to and from the controller through the third external connection pad P13. The first memory 100 may receive the chip select signal CS from the controller through the fourth external connection pad P14. The first memory 100 may receive the command address signal CAx from the controller through the fifth external connection pad P15. The first memory 100 may receive the first clock CK_t_/_c from the controller through the sixth external connection pad P16. In such a case, the data strobe signal RDQS_t/_c, the second clock WCK_t/_c, and the first clock CK_t/_c may be signals driven in a differential manner. When the data strobe signal RDQS_t/_c, the second clock WCK_t/_c, and the first clock CK_t/_c are signals driven in a differential manner, each of the first external connection pad P11, the second external connection pad P12, and the sixth external connection pad P16 may be implemented with a pair of pads.

In an embodiment, the first memory 100 may be electrically connected to another memory by using the first and second memory connection pads Pc1 and Pc2. For example, the first memory 100 may be electrically connected to the second memory 200 through the first memory connection pad Pc1 and the second memory connection pad Pc2. The first memory 100 may transmit and receive signals to and from the second memory 200 through the first and second memory connection pads Pc1 and Pc2. In an embodiment, the first memory 100 may transmit a signal to the second memory 200 through the first memory connection pad Pc1. The first memory 100 may receive a signal from the second memory 200 through the second memory connection pad Pc2.

In an embodiment, the second memory 200 may include seventh to twelfth external connection pads P21, P22, P23, P24, P25, and P26 and first and second memory connection pads Pc3 and Pc4.

In an embodiment, the second memory 200 may be electrically connected to the external device by using the seventh to twelfth external connection pads P21, P22, P23, P24, P25, and P26.

When the external device is a controller, the second memory 200 may receive signals for being controlled by the controller and transmit signals to the controller through the seventh to twelfth external connection pads P21, P22, P23, P24, P25, and P26. For example, the signals transmitted and received to and from the controller may include the first clock CK_t/_c, the command address signal CAx, the chip select signal CS, the data signal DQx, the second clock signal WCK_t/_c, and the data strobe signal RDQS_t/_c. In an embodiment, the second memory 200 may receive the first clock CK_t/_c from the controller through the seventh external connection pad P21. The second memory 200 may receive the command address signal CAx from the controller through the eighth external connection pad P22. The second memory 200 may receive the chip select signal CS from the controller through the ninth external connection pad P23. The second memory 200 may transmit and receive the data signal DQx to and from the controller through the tenth external connection pad P24. The second memory 200 may receive the second clock signal WCK_t/_c from the controller through the eleventh external connection pad P25. The second memory 200 may transmit the data strobe signal RDQS_t/_c to the controller through the twelfth external connection pad P26. In such a case, the data strobe signal RDQS_t/_c, the second clock WCK_t/_c, and the first clock CK_t/_c may be signals driven in a differential manner. When the data strobe signal RDQS_t/_c, the second clock WCK_t/_c, and the first clock CK_t/_c are signals driven in a differential manner, each of the seventh external connection pad P21, the eleventh external connection pad P25, and the twelfth external connection pad P26 may be implemented with a pair of pads.

In an embodiment, the second memory 200 may be electrically connected to another memory by using the third and fourth memory connection pads Pc3 and Pc4. For example, the second memory 200 may be electrically connected to the first memory 100 through the third memory connection pad Pc3 and the fourth memory connection pad Pc4. The second memory 200 may transmit and receive signals to and from the first memory 100 through the third and fourth memory connection pads Pc3 and Pc4. In an embodiment, the second memory 200 may receive signals from the first memory 100 through the third memory connection pad Pc3. The second memory 200 may transmit signals to the first memory 100 through the fourth memory connection pad Pc4.

In an embodiment, the sixth external connection pad P16 and the seventh external connection pad P21 may be electrically connected to each other, and each of the first and second memories 100 and 200 may receive the first clock CK_t/_c through the sixth and seventh external connection pads P16 and P21 electrically connected to each other. In addition, each of the first and second memories 100 and 200 may receive the command address signal CAx, the chip select signal CS, the data signal DQx, the second clock signal WCK_t/_c, and the data strobe signal RDQS_t/_c from the controller. That is, the first to fifth external connection pads P11, P12, P13, P14, and P15 and the eighth to twelfth external connection pads P22, P23, P24, P25, and P26 may be electrically isolated from each other, respectively.

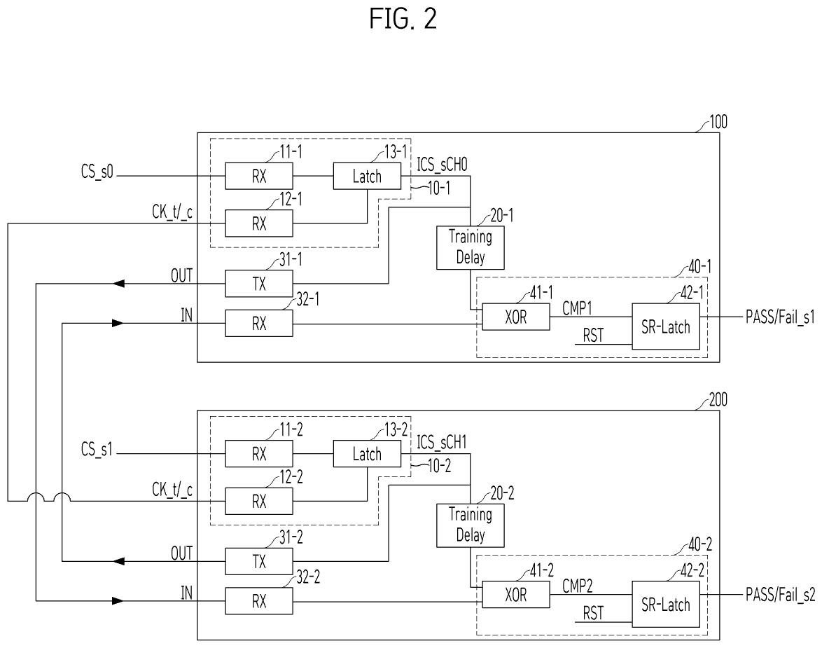

FIG. 2 is a drawing for describing a detailed configuration of the memory system in accordance with the embodiment of the present disclosure.

In an embodiment, each of the first memory 100 and the second memory 200 may perform a training operation for checking whether signals received from the controller are normally received in synchronization with the first clock CK_c/_t. In an embodiment, the first memory 100 may check whether the first chip select signal CS_s0 is normally received in synchronization with the first clock CK_c/_t. The second memory 200 may check whether the second chip select signal CS_s1 is normally received in synchronization with the first clock CK_c/_t. In addition, the first and second memories 100 and 200 may check whether the first and second chip select signals CS_s0 and CS_s1 have been received at the same timing.

In an embodiment, referring to FIG. 2, the first memory 100 includes a first synchronization check circuit 10-1, a first delay circuit (Training Delay) 20-1, a first memory transmission circuit (TX) 31-1, a first memory reception circuit (RX) 32-1, and a first timing check circuit 40-1.

In an embodiment, the first synchronization check circuit 10-1 may check whether the first chip select signal CS_s0 has been normally received in synchronization with the first clock CK_t/_c.

In an embodiment, the first synchronization check circuit 10-1 may include a first external reception circuit (RX) 11-1, a second external reception circuit (RX) 12-1, and a first latch circuit (Latch) 13-1. The first external reception circuit 11-1 may receive the first chip select signal CS_s0 transmitted from the controller through the fourth external connection pad P14, and transmit the first chip select signal CS_s0 to the first latch circuit 13-1. The second external reception circuit 12-1 may receive the first clock CK_t/_c transmitted from the controller through the sixth external connection pad P16, and transmit the first clock CK_t/_c to the first latch circuit 13-1. The first latch circuit 13-1 may receive the outputs of the first and second external reception circuits 11-1 and 12-1, and latch the signal received from the first external reception circuit 11-1 at a specific edge (for example, rising edge) of the signal received from the second external reception circuit 12-1. The first latch circuit 13-1 may output the latched signal as a first internal chip select signal ICS_sCH0. Accordingly, by checking the level of the first internal chip select signal ICS_sCH0 output from the first latch circuit 13-1, it is possible to check whether the first chip select signal CS_s0 received from the controller has been normally received in synchronization with the first clock CK_t/_c.

In an embodiment, the first delay circuit 20-1 may delay the first internal chip select signal ICS_sCH0 by a set delay time, and transmit the delayed signal to the first timing check circuit 40-1. In such a case, the delay time of the first delay circuit 20-1 may correspond to the time until a second internal chip select signal ICS_sCH1 of the second memory 200 reaches the first timing check circuit 40-1 through a second memory transmission circuit 31-2 and the first memory reception circuit 32-1.

In an embodiment, the first memory transmission circuit 31-1 may receive the first internal chip select signal ICS_sCH0 and transmit the first internal chip select signal ICS_sCH0 to the second memory 200. In such a case, the first memory transmission circuit 31-1 may transmit, to the second memory 200, the first internal chip select signal ICS_sCH0 received through the first memory connection pad Pc1 and the third memory connection pad Pc3.

In an embodiment, the first memory reception circuit 32-1 may transmit, to the first timing check circuit 40-1, a signal (for example, the second internal chip select signal ICS_sCH1) received from the second memory 200. In such a case, the first memory reception circuit 32-1 may receive a signal from the second memory 200 through the second memory connection pad Pc2 and the fourth memory connection pad Pc4. The first memory reception circuit 32-1 may transmit the signal received from the second memory 200 to the first timing check circuit 40-1.

In an embodiment, the first timing check circuit 40-1 may check whether the output of the first delay circuit 20-1 and the output of the first memory reception circuit 32-1 have been received at the same timing. In an embodiment, the first timing check circuit 40-1 may include a first exclusive OR gate (XOR) 41-1 and a first SR latch (SR-Latch) 42-1. The first exclusive OR gate 41-1 may output a low signal as a first comparison result signal CMP1 when the outputs of the first delay circuit 20-1 and the first memory reception circuit 32-1 are at the same level, and output a high signal as the first comparison result signal CMP1 when the outputs are at different levels. The first SR latch 42-1 may output a first check result signal PASS/Fail_s1 at a low level when a reset signal RST is enabled. When the output of the first exclusive OR gate 41-1 is at a high level and the reset signal RST is disabled, the first SR latch 42-1 may change the level of the first check result signal PASS/Fail_s1 to a high level. That is, the first SR latch 42-1 may reset the first check result signal PASS/Fail_s1 to a low level by the reset signal RST, and then change the first check result signal PASS/Fail_s1 based on the output level of the first exclusive OR gate 41-1. When the output level of the first exclusive OR gate 41-1 is a low level, the first SR latch 42-1 may maintain the level of the first check result signal PASS/Fail_s1 that is reset, that is, the low level of the first check result signal PASS/Fail_s1. Accordingly, when the first check result signal PASS/Fail_s1 is reset by enabling the reset signal RST and then the outputs of the first delay circuit 20-1 and the first memory reception circuit 32-1 that are received are at different levels, the first timing check circuit 40-1 may change the level of the first check result signal PASS/Fail_s1 to a high level. As a result, when the outputs of the first delay circuit 20-1 and the first memory reception circuit 32-1 are received at the same level and at the same timing, the first timing check circuit 40-1 may output the low-level first check result signal PASS/Fail_s1.

In an embodiment, the second memory 200 may include a second synchronization check circuit 10-2, a second delay circuit (Training Delay) 20-2, a second memory transmission circuit (TX) 31-2, a second memory reception circuit (RX) 32-2, and a second timing check circuit 40-2.

In an embodiment, the second synchronization check circuit 10-2 may check whether the second chip select signal CS_s1 has been normally received in synchronization with the first clock CK_t/_c.

In an embodiment, the second synchronization check circuit 10-2 may include a third external reception circuit (RX) 11-2, a fourth external reception circuit (RX) 12-2, and a second latch circuit (Latch) 13-2. The third external reception circuit 11-2 may receive the second chip select signal CS_s1 transmitted from the controller through the ninth external connection pad 23, and transmit the second chip select signal CS_s1 to the second latch circuit 13-2. The fourth external reception circuit 12-2 may receive the first clock CK_t/_c transmitted from the controller through the seventh external connection pad P21, and transmit the first clock CK_t/_c to the second latch circuit 13-2. The second latch circuit 13-2 may receive the outputs of the third and fourth external reception circuits 11-2 and 12-2, and latch the signal received from the third external reception circuit 11-2 at a specific edge (for example, rising edge) of the signal received from the fourth external reception circuit 12-2. The second latch circuit 13-2 may output the latched signal as the second internal chip select signal ICS_sCH1. Accordingly, by checking the level of the second internal chip select signal ICS_sCH1 output from the second latch circuit 13-2, it is possible to check whether the second chip select signal CS_s1 received from the controller has been normally received in synchronization with the first clock CK_t/_c.

In an embodiment, the second delay circuit (Training Delay) 20-2 may delay the second internal chip select signal ICS_sCH1 by a set delay time, and transmit the delayed signal to the second timing check circuit 40-2. In such a case, the delay time of the second delay circuit 20-2 may correspond to the time until the first internal chip select signal ICS_sCH0 of the first memory 100 reaches the second timing check circuit 40-2 through the first memory transmission circuit 31-1 and the second memory reception circuit 31-2.

In an embodiment, the second memory transmission circuit 31-2 may receive the second internal chip select signal ICS_sCH1 and transmit the second internal chip select signal ICS_sCH1 to the first memory 100. In such a case, the second memory transmission circuit 31-2 may transmit, to the first memory 100, the second internal chip select signal ICS_sCH1 received through the fourth memory connection pad Pc4 and the second memory connection pad Pc2.

In an embodiment, the second memory reception circuit 32-2 may transmit, to the second timing check circuit 40-2, a signal (for example, the first internal chip select signal ICS_sCH0) received from the first memory 200. In such a case, the second memory reception circuit 32-2 may receive a signal from the first memory 100 through the first memory connection pad Pc1 and the third memory connection pad Pc3. The second memory reception circuit 32-2 may transmit the signal received from the first memory 100 to the second timing check circuit 40-2.

In an embodiment, the second timing check circuit 40-2 may check whether the output of the second delay circuit 20-2 and the output of the second memory reception circuit 32-2 have been received at the same timing. In an embodiment, the second timing check circuit 40-2 may include a second exclusive OR gate (XOR) 41-2 and a second SR latch (SR-Latch) 42-2. The second exclusive OR gate 41-2 may output a low signal as a second comparison result signal CMP2 when the outputs of the second delay circuit 20-2 and the second memory reception circuit 32-2 are at the same level, and output a high signal as the second comparison result signal CMP2 when the outputs are at different levels. The second SR latch 42-2 may output a second check result signal PASS/Fail_s2 at a low level when the reset signal RST is enabled. When the output of the second exclusive OR gate 41-2 is at a high level and the reset signal RST is disabled, the second SR latch 42-2 may change the level of the second check result signal PASS/Fail_s2 to a high level. That is, the second SR latch 42-2 may reset the second check result signal PASS/Fail_s2 to a low level by the reset signal RST, and then change the second check result signal PASS/Fail_s2 based on the output level of the second exclusive OR gate 41-2. When the output level of the second exclusive OR gate 41-2 is a low level, the second SR latch 42-2 may maintain the level of the second check result signal PASS/Fail_s2 that is reset, that is, the low level of the second check result signal PASS/Fail_s2. Accordingly, when the second check result signal PASS/Fail_s2 is reset by enabling the reset signal RST and then the outputs of the second delay circuit 20-2 and the second memory reception circuit 32-2 that are received are at different levels, the second timing check circuit 40-2 may change the level of the second check result signal PASS/Fail_s2 to a high level. As a result, when the outputs of the second delay circuit 20-1 and the second memory reception circuit 32-2 are received at the same level and at the same timing, the second timing check circuit 40-2 may output the low-level second check result signal PASS/Fail_s2.

As a result, when the first internal chip select signal ICS_sCH0 generated by the first memory 100 and the second internal chip select signal ICS_sCH1 received from the second memory 200 are received at the same level and at the same timing, the first memory 100 may output the first check result signal PASS/Fail_s1 at a low level. In addition, when the second internal chip select signal ICH_sCH1 generated by the second memory 200 and the first internal chip select signal ICS_sCH0 received from the first memory 100 are received at the same level and at the same timing, the second memory 200 may output the second check result signal PASS/Fail_s2 at a low level.

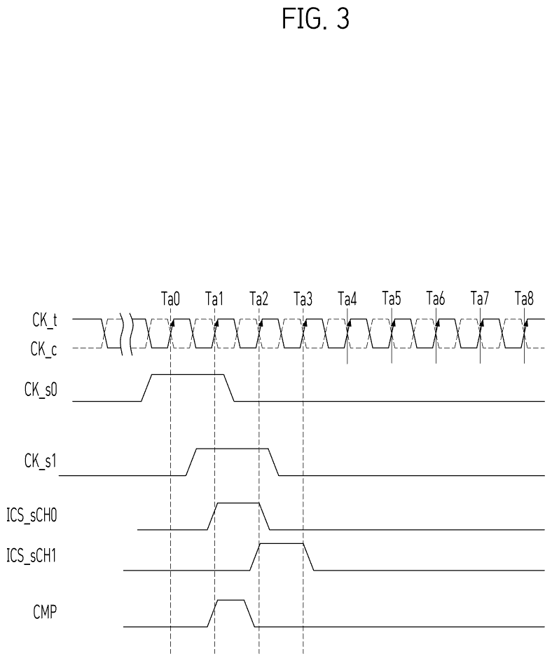

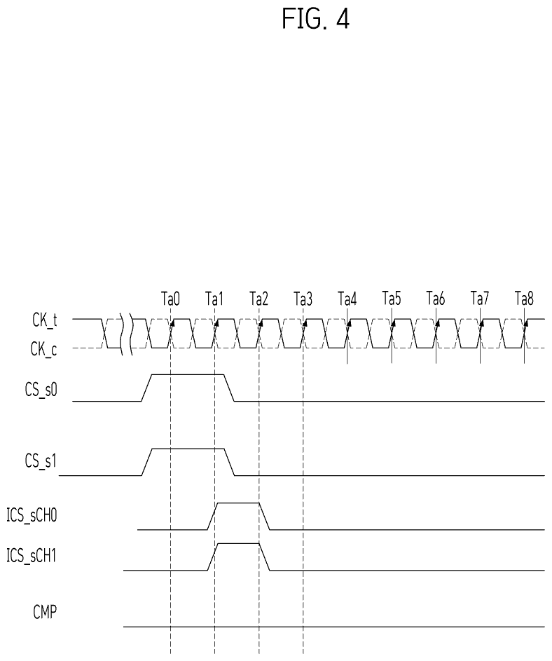

FIGS. 3 and 4 are timing diagrams for describing the operation of the memory system in accordance with the embodiment of the present disclosure.

FIG. 3 is a timing diagram illustrating a case in which the first and second memories 100 and 200 receive signals transmitted from the external device, at different timings, respectively. For example, the external device is a controller, and the signals transmitted from the external device are the first chip select signal CS_s0 and the second chip select signal CS_s1. In such a case, FIG. 3 illustrates an embodiment in which the first clock CK_t/_c is a signal driven in a differential manner. The first clock CK_t/_c includes a clock CK_t and a clock bar CK_c, and the phases of the clock CK_t and the clock bar CK_c are opposite to each other.

Referring to FIG. 3, the first memory 100 may receive the first chip select signal CS_so. In such a case, the first memory 100 may receive the first chip select signal CS_s0 at a timing earlier than a first timing Ta0. The second memory 200 may receive the second chip select signal CS_s1. In such a case, the second memory 200 may receive the second chip select signal CS_s1 at a timing earlier than a second timing Ta1. Each of the first timing Ta0, the second timing Ta1, a third timing Ta2, a fourth timing Ta3, a fifth timing Ta4, a sixth timing Ta5, a seventh timing Ta6, an eighth timing Ta7, and a ninth timing Ta8 is a timing at which the first clock CK_t/_c transitions. For example, each of the first to ninth timings Ta0 to Ta8 is a timing corresponding to a rising edge of the clock CK_t. Each of the first to ninth timings Ta0 to Ta8 is described as a timing corresponding to a falling edge of the clock bar CK_c.

In an embodiment, the first synchronous circuit 10-1 of the first memory 100 may latch the first chip select signal CS_s0 at each of the first to ninth timings Ta0 to Ta8 to generate the first internal chip select signal ICS_sCH0. In such a case, the first chip select signal CS_s0 reaches the first memory 100 at a timing earlier than the first timing Ta0, but the timing at which the first chip select signal CS_s0 is received in the first latch circuit 13-1 through the first external reception circuit 11-1 is later than the first timing Ta0.

Accordingly, the timing at which the level of the first internal chip select signal ICS_sCH0 changes is the second timing Ta1. At the second timing Ta1, because the first chip select signal CS_s0 is at a high level, the first synchronization check circuit 10-1 may transition the level of the first internal chip select signal ICS_sCH0 to a high level at the second timing Ta1. At the third timing Ta2, because the first chip select signal CS_s0 is at a low level, the first synchronization check circuit 10-1 may transition the level of the first internal chip select signal ICS_sCH0 to a low level at the third timing Ta2.

In an embodiment, the second synchronization circuit 10-2 of the second memory 200 may also latch the second chip select signal CS_s1 at each of the first to ninth timings Ta0 to Ta8 to generate the second internal chip select signal ICS_sCH1. In such a case, the second chip select signal CS_s1 reaches the second memory 200 at a timing earlier than the second timing Ta1, but the timing at which the second chip select signal CS_s1 is received in the second latch circuit 13-2 through the third external reception circuit 11-2 is later than the second timing Ta1.

Accordingly, the point in time at which the level of the second internal chip select signal ICS_sCH1 changes is the third timing Ta2. At the third timing Ta2, because the second chip select signal CS_s1 is at a high level, the second synchronization check circuit 10-2 may transition the level of the second internal chip select signal ICS_sCH1 to a high level at the third timing Ta2. At the fourth timing Ta3, because the second chip select signal CS_s1 is at a low level, the second synchronization check circuit 10-2 may transition the level of the second internal chip select signal ICS_sCH1 to a low level at the fourth timing Ta3.

In an embodiment, the first memory 100 may receive the second internal chip select signal ICS_sCH1 from the second memory 200 through the second and fourth memory connection pads Pc2 and PC4.

In an embodiment, the first timing check circuit 40-1 of the first memory 100 may receive the first internal chip select signal ICH_sCH0 and the second internal chip select signal ICS_sCH1.

In an embodiment, the first exclusive OR gate 41-1 of the first timing check circuit 40-1 may generate the first comparison result signal CMP1 that is enabled to a high level between the second timing Ta1 and the third timing Ta2 where the levels of the first and second internal chip select signals ICS_sCH0 and ICS_sCH1 are different from each other. When the level of the first comparison signal CMP1 transitions to a high level, the first timing check circuit 40-1 may transition, to a high level, and the level of the first check result signal PASS/Fail_s1 may be reset to a low level.

In an embodiment, the second memory 200 may receive the first internal chip select signal ICS_sCH0 from the first memory 100 through the first and third memory connection pads Pc1 and Pc3.

In an embodiment, the second timing check circuit 40-2 of the second memory 200 may receive the first internal chip select signal ICH_sCH0 and the second internal chip select signal ICS_sCH1.

In an embodiment, the second exclusive OR gate 41-2 of the second timing check circuit 40-2 may generate the second comparison result signal CMP2 that is enabled to a high level between the second timing Ta1 and the third timing Ta2 where the levels of the first and second internal chip select signals ICS_sCH0 and ICS_sCH1 are different from each other. When the level of the second comparison signal CMP2 transitions to a high level, the second timing check circuit 40-2 may transition, to a high level, and the level of the second check result signal PASS/Fail_s2 may be reset to a low level.

FIG. 4 is a timing diagram illustrating a case in which signals transmitted from the external device are received in the first and second memories 100 and 200 at the same timing. For example, the external device is a controller, and the signals transmitted from the external device are the first chip select signal CS_s0 and the second chip select signal CS_s1. In such a case, FIG. 4 illustrates an embodiment in which the first clock CK_t/_c is a signal driven in a differential manner. The first clock CK_t/_c includes a clock CK_t and a clock bar CK_c, and the phases of the clock CK_t and the clock bar CK_c are opposite to each other.

Referring to FIG. 4, the first memory 100 may receive the first chip select signal CS_so. In such a case, the first memory 100 may receive the first chip select signal CS_s0 at a timing earlier than the first timing Ta0. The second memory 200 may receive the second chip select signal CS_s1. In such a case, the second memory 200 may receive the second chip select signal CS_s1 at a timing earlier than the first timing Ta0. Each of the first timing Ta0, the second timing Ta1, the third timing Ta2, the fourth timing Ta3, the fifth timing Ta4, the sixth timing Ta5, the seventh timing Ta6, the eighth timing Ta7, and the ninth timing Ta8 is a timing at which the first clock CK_t/_c transitions. For example, each of the first to ninth timings Ta0 to Ta8 is a timing corresponding to the rising edge of the clock CK_t. Each of the first to ninth timings Ta0 to Ta8 is described as a timing corresponding to the falling edge of the clock bar CK_c.

In an embodiment, the first synchronous circuit 10-1 of the first memory 100 may latch the first chip select signal CS_s0 at each of the first to ninth timings Ta0 to Ta8 to generate the first internal chip select signal ICS_sCH0. In such a case, the first chip select signal CS_s0 reaches the first memory 100 at a timing earlier than the first timing Ta0, but the timing at which the first chip select signal CS_s0 is received in the first latch circuit 13-1 through the first external reception circuit 11-1 is later than the first timing Ta0.

Accordingly, the timing at which the level of the first internal chip select signal ICS_sCH0 changes is the second timing Ta1. At the second timing Ta1, because the first chip select signal CS_s0 is at a high level, the first synchronization check circuit 10-1 may transition the level of the first internal chip select signal ICS_sCH0 to a high level at the second timing Ta1. At the third timing Ta2, because the first chip select signal CS_s0 is at a low level, the first synchronization check circuit 10-1 may transition the level of the first internal chip select signal ICS_sCH0 to a low level at the third timing Ta2.

In an embodiment, the second synchronization circuit 10-2 of the second memory 200 may also latch the second chip select signal CS_s1 at each of the first to ninth timings Ta0 to Ta8 to generate the second internal chip select signal ICS_sCH1. In such a case, the second chip select signal CS_s1 reaches the second memory 200 at a timing earlier than the first timing Ta0, but the timing at which the second chip select signal CS_s1 is received in the second latch circuit 13-2 through the third external reception circuit 11-2 is later than the first timing Ta0.

Accordingly, the point in time at which the level of the second internal chip select signal ICS_sCH1 changes is the second timing Ta1. At the second timing Ta1, because the second chip select signal CS_s1 is at a high level, the second synchronization check circuit 10-2 may transition the level of the second internal chip select signal ICS_sCH1 to a high level at the second timing Ta1. At the third timing Ta2, because the second chip select signal CS_s1 is at a low level, the second synchronization check circuit 10-2 may transition the level of the second internal chip select signal ICS_sCH1 to a low level at the third timing Ta2.

In an embodiment, the first memory 100 may receive the second internal chip select signal ICS_sCH1 from the second memory 200 through the second and fourth memory connection pads Pc2 and PC4.

In an embodiment, the first timing check circuit 40-1 of the first memory 100 may receive the first internal chip select signal ICH_sCH0 and the second internal chip select signal ICS_sCH1.

In an embodiment, because there is no period in which the levels of the first and second internal chip select signals ICS_sCH0 and ICS_sCH1 are different from each other, the first exclusive OR gate 41-1 of the first timing check circuit 40-1 may maintain the first comparison result signal CMP1 at a low level. When the first comparison result signal CMP1 is maintained at a low level, the first timing check circuit 40-1 may maintain the first check result signal PASS/Fail_s1 reset to a low level.

In an embodiment, the second memory 200 may receive the first internal chip select signal ICS_sCH0 from the first memory 100 through the first and third memory connection pads Pc1 and Pc3.

In an embodiment, the second timing check circuit 40-2 of the second memory 200 may receive the first internal chip select signal ICH_sCH0 and the second internal chip select signal ICS_sCH1.

In an embodiment, because there is no period in which the levels of the first and second internal chip select signals ICS_sCH0 and ICS_sCH1 are different from each other, the second exclusive OR gate 41-2 of the second timing check circuit 40-2 may maintain the second comparison result signal CMP2 at a low level. When the second comparison result signal CMP2 is maintained at a low level, the second timing check circuit 40-2 may maintain the second check result signal PASS/Fail_s2 reset to a low level.

Accordingly, referring to FIGS. 3 and 4, when the reception timings of the first chip select signal CS_s0 and the second chip select signal CS_s1 in the first and second memories 100 and 200 are different from each other, the memory system may output the first and second check result signals PASS/Fail_s0 and PASS/Fail_s1 at a high level. On the other hand, when the reception timings of the first chip select signal CS_s0 and the second chip select signal CS_s1 in the first and second memories 100 and 200 are equal to each other, the memory system may output the first and second check result signals PASS/Fail_s0 and PASS/Fail_s1 at a low level.

As a result, the memory system in accordance with the embodiment of the present disclosure may check whether signals transmitted from the external device (for example, the controller) have been simultaneously received in respective memories.

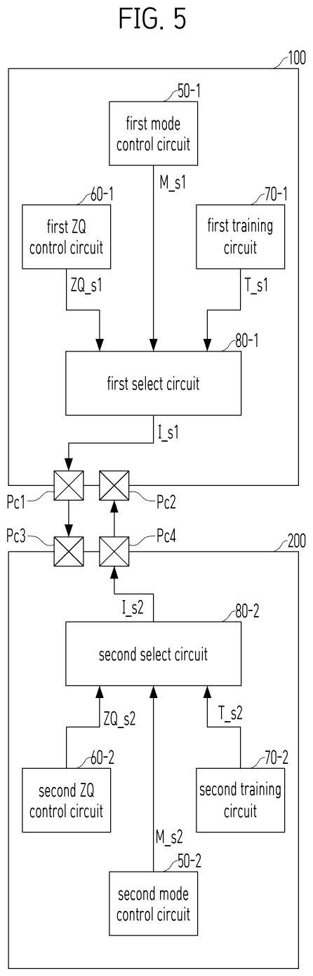

FIG. 5 is a diagram for describing a configuration of a memory system in accordance with another embodiment of the present disclosure.

Referring to FIG. 5, the memory system may include a plurality of memories 100 and 200 that transmit and receive signals to and from each other. For example, the plurality of memories 100 and 200 may include a first memory 100 and a second memory 200. The first and second memories 100 and 200 may transmit and receive signals to and from each other.

In an embodiment, the first memory 100 transmits its own ZQ calibration information ZQ_s1 or training result information T_s1 to the second memory 200. The first memory 100 may also receive ZQ calibration information ZQ_s2 or training result information T_s2 of the second memory 200 from the second memory 200. In such a case, the ZQ calibration information ZQ_s1 of the first memory 100 is referred to as first ZQ calibration information ZQ_s1, and the training result information T_s1 thereof is referred to as first training result information T_s1. In addition, the ZQ calibration information ZQ_s2 of the second memory 200 is referred to as second ZQ calibration information ZQ_s2, and the training result information T_s2 thereof is referred to as second training result information T_s2.

In an embodiment, the first memory 100 may include a first mode control circuit 50-1, a first ZQ control circuit 60-1, a first training circuit 70-1, and a first selection circuit 80-1.

In an embodiment, the first mode control circuit 50-1 may select an operation mode of the first memory 100. In an embodiment, the first mode control circuit 50-1 may select one of a calibration operation mode and a training mode. In such a case, the first mode control circuit 50-1 may output a first mode select signal M_s1 having a level corresponding to the selected operation mode. For example, when the first memory 100 operates in the calibration operation mode by the first mode control circuit 50-1, the first mode control circuit 50-1 may output the mode select signal M_s1 at a first level. On the other hand, when the first memory 100 operates in the training mode by the first mode control circuit 50-1, the first mode control circuit 50-1 may output the mode select signal M_s1 at a second level. The first level and the second level are different levels.

In an embodiment, the first ZQ control circuit 60-1 may perform a ZQ calibration operation on the first memory 100. The first ZQ control circuit 60-1 may generate the first ZQ calibration information ZQ_s1 having a code value corresponding to an external resistor electrically connected to the first memory 100, through the ZQ calibration operation of the first memory 100.

In an embodiment, the first training circuit 70-1 may perform a training operation of the first memory 100. The first training circuit 70-1 may output the result of performing the training operation as the first training result information T_s1. In such a case, the first training circuit 70-1 may include the components of the first memory 100 illustrated in FIG. 2, for example, the first synchronization check circuit 10-1, the first delay circuit 20-1, and the first timing check circuit 40-1. The first training circuit 70-1 including the components of the first memory 100 of FIG. 2 may output, as the first check result signal PASS/Fail_s1, whether the first internal chip select signal ICS_sCH0 received by the first memory 100 in synchronization with the first clock CK_t/_c and the second internal chip select signal ICS_sCH1 of the second memory 200 have been received at the same timing. The first training result information T_s1 being the output of the first training circuit 70-1 may include the first check result signal PASS/Fail_s1.

In an embodiment, the first selection circuit 80-1 may transmit one of the first calibration information ZQ_s1 and the first training result information T_s1 to the second memory 200 as a first internal select signal I_s1 based on the first mode select signal M_s1. For example, when the first mode select signal M_s1 is at a first level, the first selection circuit 80-1 may transmit the first calibration information ZQ_s1 to the second memory 200 as the first internal select signal I_s1. On the other hand, when the first mode select signal M_s1 is at a second level, the first selection circuit 80-1 may transmit the first training result information T_s1 to the second memory 200 as the first internal select signal I_s1.

When the first selection circuit 80-1 of the first memory 100 may transmit the first internal select signal I_s1 to the second memory 200, the first internal select signal I_s1 may be transmitted to the second memory 200 through the first memory connection pad Pc1 of the first memory 100 and the third memory connection pad Pc3 of the second memory 200.

In an embodiment, the second memory 200 may transmits its own ZQ calibration information ZQ_s2 or training result information T_s2 to the first memory 100. In addition, the second memory 200 may receive the ZQ calibration information ZQ_s1 or the training result information T_s1 of the first memory 100 from the first memory 100.

In an embodiment, the second memory 200 may include a second mode control circuit 50-2, a second ZQ control circuit 60-2, a second training circuit 70-2, and a second selection circuit 80-2.

In an embodiment, the second mode control circuit 50-2 may select an operation mode of the second memory 200. In an embodiment, the second mode control circuit 50-2 may select one of the calibration operation mode and the training mode. In such a case, the second mode control circuit 50-2 may output a second mode select signal M_s2 having a level corresponding to the selected operation mode. For example, when the second memory 200 operates in the calibration operation mode by the second mode control circuit 50-2, the second mode control circuit 50-2 may output the mode select signal M_s2 at a first level. On the other hand, when the second memory 200 operates in the training mode by the second mode control circuit 50-2, the second mode control circuit 50-2 may output the mode select signal M_s2 at a second level. The first level and the second level are different levels.

In an embodiment, the second ZQ control circuit 60-2 may perform a ZQ calibration operation on the second memory 200. The second ZQ control circuit 60-2 may generate the second ZQ calibration information ZQ_s2 having a code value corresponding to an external resistor electrically connected to the second memory 200, through the ZQ calibration operation of the second memory 200. In such a case, the first memory 100 and the second memory 200 may share the external resistor. That is, each of the first and second memories 100 and 200 may perform the calibration operation by using the same external resistor.

In an embodiment, the second training circuit 70-2 may perform the training operation on the second memory 200. The second training circuit 70-2 may output the result of performing the training operation as the second training result information T_s2. In such a case, the second training circuit 70-2 may include the components of the second memory 200 illustrated in FIG. 2, for example, the second synchronization check circuit 10-2, the second delay circuit 20-2, and the second timing check circuit 40-2. The second training circuit 70-2 including the components of the second memory 200 of FIG. 2 may output, as the second check result signal PASS/Fail_s2, whether the second internal chip select signal ICS_sCH1 received by the second memory 200 in synchronization with the first clock CK_t/_c and the first internal chip select signal ICS_sCH0 of the first memory 100 have been received at the same timing. The second training result information T_s2 being the output of the second training circuit 70-2 may include the second check result signal PASS/Fail_s2.

In an embodiment, the second selection circuit 80-2 may transmit one of the second calibration information ZQ_s2 and the second training result information T_s2 to the first memory 100 as a second internal select signal I_s2 based on the second mode select signal M_s2. For example, when the second mode select signal M_s2 is at a first level, the second selection circuit 80-2 may transmit the second calibration information ZQ_s2 to the first memory 100 as the second internal select signal I_s2. On the other hand, when the second mode select signal M_s2 is at a second level, the second selection circuit 80-2 may transmit the second training result information T_s2 to the first memory 100 as the second internal select signal I_s2. When the second selection circuit 80-2 of the second memory 200 transmits the second internal select signal I_s2 to the first memory 100, the second internal select signal I_s2 may be transmitted to the first memory 100 through the fourth memory connection pad Pc4 of the second memory 200 and the second memory connection pad Pc2 of the first memory 100.

As described above, the memory system in accordance with another embodiment of the present disclosure can be configured such that a plurality of memories each having a plurality of memory connection pads can transmit and receive one of a plurality of internal signals to and from each other according to an operation mode.

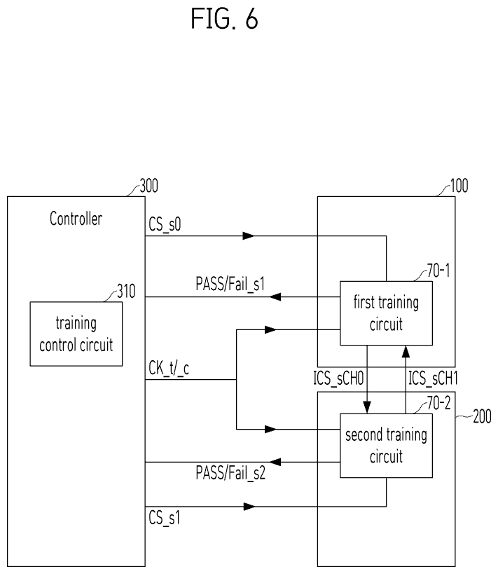

FIG. 6 is a diagram for describing a configuration of a memory system in accordance with further another embodiment of the present disclosure. In FIG. 6, a training operation of the memory system in accordance with further another embodiment of the present disclosure is described.

Referring to FIG. 6, the memory system in accordance with further another embodiment of the present disclosure may include a first memory 100, a second memory 200, and a controller 300.

In an embodiment, the first memory 100 may receive a first clock CK_t/_c and a first chip select signal CS_s0 from the controller 300. The first memory 100 may generate a first internal chip select signal ICS_sCH0 by synchronizing the first chip select signal CS_s0 with the first clock CK_t/_c. The first memory 100 may receive a second internal chip select signal ICS_sCH1 from the second memory 200. The first memory 100 may check whether the generation timing of the first internal chip select signal ICS_sCH0 and the reception timing of the second internal chip select signal ICS_sCH1 are equal to each other, and transmit the check result to the controller 300 as a first check result signal PASS/Fail_s1. When the generation timing of the first internal chip select signal ICS_sCH0 and the reception timing of the second internal chip select signal ICS_sCH1 are equal to each other, the first memory 100 may transmit the first check result signal PASS/Fail_s1 at a low level to the controller 300. On the other hand, when the generation timing of the first internal chip select signal ICS_sCH0 and the reception timing of the second internal chip select signal ICS_sCH1 are different from each other, the first memory 100 may transmit the first check result signal PASS/Fail_s1 at a high level to the controller 300. The first memory 100 may include a first training circuit 70-1 that may generate the first internal chip select signal ICS_sCH0 based on the first chip select signal CS_s0 and the first clock CK_t/_c, and compare the first internal chip select signal ICS_sCH0 with the second internal chip select signal ICS_sCH1 of the second memory 200 to generate the first check result signal PASS/Fail_s1.

In an embodiment, the second memory 200 may receive the first clock CK_t/_c and a second chip select signal CS_s1 from the controller 300. The second memory 200 may generate the second internal chip select signal ICS_sCH1 by synchronizing the second chip select signal CS_s1 with the first clock CK_t/_c. The second memory 200 may receive the first internal chip select signal ICS_sCH0 from the first memory 100. The second memory 200 may check whether the generation timing of the second internal chip select signal ICS_sCH1 and the reception timing of the first internal chip select signal ICS_sCH0 are equal to each other, and transmit the check result to the controller 300 as a second check result signal PASS/Fail_s2. When the generation timing of the second internal chip select signal ICS_sCH1 and the reception timing of the first internal chip select signal ICS_sCH0 are equal to each other, the second memory 200 may transmit the second check result signal PASS/Fail_s2 at a low level to the controller 300. On the other hand, when the generation timing of the second internal chip select signal ICS_sCH1 and the reception timing of the first internal chip select signal ICS_sCH0 are different from each other, the second memory 200 may transmit the second check result signal PASS/Fail_s2 at a high level to the controller 300. The second memory 200 may include a second training circuit 70-2 that may generate the second internal chip select signal ICS_sCH1 based on the second chip select signal CS_s1 and the first clock CK_t/_c, and compares the second internal chip select signal ICS_sCH1 with the first internal chip select signal ICS_sCH0 of the first memory 100 to generate the second check result signal PASS/Fail_s2.

In an embodiment, the controller 300 may provide the first chip select signal CS_s0 and the first clock CK_t/_c to the first memory 100, and provide the second chip select signal CS_s1 and the first clock CK_t/_c to the second memory 200. The controller 300 may receive the first check result signal PASS/Fail_s1 from the first memory 100, and receive the second check result signal PASS/Fail_s2 from the second memory 200. The controller 300 may change the output timing of at least one of the first chip select signal CS_s0 and the second chip select signal CS_s1 based on the first check result signal PASS/Fail_s1 and the second check result signal PASS/Fail_s2. In an embodiment, the controller 300 may change the output timing of at least one of the first and second chip select signals CS_s0 and CS_s1 until both first and second check result signals PASS/Fail_s1 and PASS/Fail_s2 have the same level.

In an embodiment, more specifically, the controller 300 may change the output timing of at least one of the first and second chip select signals CS_s0 and CS_s1 until both first and second check result signals PASS/Fail_s1 and PASS/Fail_s2 have the same low level. The controller 300 may include a training control circuit 310 that may change the output timing of at least one of the first and second chip select signals CS_s0 and CS_s1 based on the first and second check result signals PASS/Fail_s1 and PASS/Fail_s2 during a training operation.

As a result, the controller 300 may change the output timing of at least one of the first and second chip select signals CS_s0 and CS_s1 until the first and second memories 100 and 200 simultaneously receive the first and second chip select signals CS_s0 and CS_s1.

In an embodiment, more specifically, the controller 300 may change the output timing of the second chip select signal CS_s1 out of the first and second chip select signals CS_s0 and CS_s1 until the first and second check result signals PASS/Fail_s1 and PASS/Fail_s2 have the same level, that is, a low level. As a result, until the first and second check result signals PASS/Fail_s1 and PASS/Fail_s2 all have the same level and thus the reception timings of the first and second chip select signals CS_s0 and CS_s1 in the first and second memories 100 and 200 are equal to each other, the controller 300 may push or pull the output timing of the second chip select signal CS_s1.

Accordingly, the memory system in accordance with further another embodiment of the present disclosure may change the output timing of at least one of the first and second chip select signals CS_s0 and CS_s1 during a training operation until the reception timings of the first and second chip select signals CS_s0 and CS_s1, which are respectively provided to the first and second memories 100 and 200, in the first and second memories 100 and 200 are equal to each other.

Consequently, the memory system in accordance with further another embodiment of the present disclosure can control a plurality of memories provided therein at the same timing.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A memory system comprising:
a first memory configured to receive a first signal in synchronization with a clock; and
a second memory configured to receive a second signal in synchronization with the clock,
wherein the first memory is configured to transmit the received first signal to the second memory, and the second memory is configured to transmit the received second signal to the first memory.

2. The memory system of claim 1, wherein each of the first and second memories comprises:
a timing check circuit configured to check whether a reception timing of the first signal and a reception timing of the second signal are equal to each other.

3. The memory system of claim 1, wherein the timing check circuit comprises:
an exclusive OR gate configured to compare whether a level of the first signal in synchronization with the clock and a level of the second signal in synchronization with the clock are equal to each other; and
an SR latch configured to generate a check result signal based on an output signal of the exclusive OR gate and a reset signal.

4. The memory system of claim 1, wherein the first signal is a first chip select signal and the second signal is a second chip select signal.

5. The memory system of claim 1,
wherein the first memory comprises a first memory connection pad and a second memory connection pad electrically connected to the second memory, and
wherein the second memory comprises a third memory connection pad and a fourth memory connection pad electrically connected to the first memory.

6. The memory system of claim 5,
wherein the first memory is configured to transmit the first signal to the second memory through the first memory connection pad and the third memory connection pad, and
wherein the second memory is configured to transmit the second signal to the first memory through the second memory connection pad and the fourth memory connection pad.

7. The memory system of claim 6, wherein the first memory further comprises:
a first mode control circuit configured to select an operation mode of the first memory, and generate a first mode select signal corresponding to the selected operation mode;
a first ZQ control circuit configured to perform a ZQ calibration operation on the first memory to generate first ZQ calibration information; and
a first selection circuit configured to transmit one of the first ZQ calibration information and the first signal to the second memory through the first and third memory connection pads based on the first mode select signal.

8. The memory system of claim 7, wherein the second memory further comprises:
a second mode control circuit configured to select an operation mode of the second memory, and generate a second mode select signal corresponding to the selected operation mode;
a second ZQ control circuit configured to perform a ZQ calibration operation of the second memory to generate second ZQ calibration information; and
a second selection circuit configured to transmit one of the second ZQ calibration information and the second signal to the first memory through the second and fourth memory connection pads based on the second mode select signal.

9. A memory system comprising:
a first memory comprising a plurality of first connection pads configured to electrically connect with a controller and a plurality of first memory connection pads configured to electrically connect with a second memory; and
the second memory comprising a plurality of second connection pads configured to electrically connect with the controller and a plurality of second memory connection pads configured to electrically connect with the first memory.

10. The memory system of claim 9, wherein the first memory and the second memory are configured to transmit and receive signals through the plurality of first memory connection pads and the plurality of second memory connection pads.

11. The memory system of claim 9, wherein at least one of the plurality of first connection pads is electrically connected to at least one of the plurality of second connection pads.

12. The memory system of claim 11, wherein the first and second memories are configured to receive a clock through the at least one first connection pad and the at least one second connection pad electrically connected to each other.

13. The memory system of claim 12, wherein the first memory is configured to receive a first chip select signal through one of first connection pads electrically isolated from each other, among the plurality of first memory connection pads, and
the second memory is configured to receive a second chip select signal through one of second connection pads electrically isolated from each other, among the plurality of second memory connection pads.

14. The memory system of claim 13, wherein the first memory comprises:
a first synchronization check circuit configured to generate a first internal chip select signal by synchronizing the first chip select signal with the clock;
a first memory transmission circuit configured to transmit the first internal chip select signal to the second memory;
a first memory reception circuit configured to receive a second internal chip select signal from the second memory; and
a first timing check circuit configured to check whether reception timings of the first internal chip select signal and the second internal chip select signal are equal to each other.

15. The memory system of claim 14, wherein the second memory comprises:
a second synchronization check circuit configured to generate the second internal chip select signal by synchronizing the second chip select signal with the clock;
a second memory transmission circuit configured to transmit the second internal chip select signal to the first memory;
a second memory reception circuit configured to receive the first internal chip select signal from the first memory; and
a second timing check circuit configured to check whether reception timings of the second internal chip select signal and the first internal chip select signal are equal to each other.

16. The memory system of claim 15, wherein the first memory and the second memory are configured to transmit and receive the first and second internal chip select signals through the plurality of first memory connection pads and the plurality of second memory connection pads.

17. The memory system of claim 15, wherein each of the first and second timing check circuits comprises:
an exclusive OR gate configured to generate a comparison result signal based on the first and second internal chip select signals; and
an SR latch configured to receive a reset signal and an output signal of the exclusive OR gate.

18. A memory system comprising:
a first memory configured to receive a first chip select signal in synchronization with a clock;
a second memory configured to receive a second chip select signal in synchronization with the clock; and
a controller configured to transmit the first chip select signal to the first memory and transmit the second chip select signal to the second memory,
wherein the first memory is configured to transmit the received first chip select signal to the second memory as a first internal chip select signal, and the second memory is configured to transmit the received second chip select signal to the first memory as a second internal chip select signal.

19. The memory system of claim 18, wherein each of the first and second memories is configured to:
check whether reception timings of the first internal chip select signal and the second internal chip select signal are equal to each other to generate a first check result signal and a second check result signal; and
transmit the first and second check result signals to the controller.

20. The memory system of claim 19, wherein based on the first and second check result signals, the controller is configured to change an output timing of at least one of the first and second chip select signals until the reception timings of the first and second internal chip select signals in the first and second memories are equal to each other.
